(19) United States
(12) Patent Application Publication
(10) Pub. No.: US 2026/0290455 A1
(43) Pub. Date: Sep. 24, 2026

(54) TERNARY CONTENT ADDRESSABLE MEMORY (TCAM) HAVING VARIABLE SIZE ENTRIES

(71) Applicant: NXP B.V., Eindhoven (NL)

(72) Inventors: John Pillar, AUSTIN, TX (US); Sathish Vallipuram, AUSTIN, TX (US); Braden Kenneth Bale, AUSTIN, TX (US)

(21) Appl. No.: 19/085,648

(22) Filed: Mar. 20, 2025

(51) Int. Cl. G11C 15/04; G11C 11/4097

(52) U.S. Cl. CPC G11C 15/04; G11C 11/4097

(57) ABSTRACT

A ternary content addressable memory (TCAM) receives N beats in a current clock cycle, corresponding to N portions of a look-up key. Each line has a corresponding cumulative line match (CLM) bit. An asserted CLM bit indicates that an isolated line match for the line has occurred in a previous cycle. Prerequisite circuitry for each line, in response to an isolated line match of a current line with any one of the N beats and both first and second conditions being met, indicates that the corresponding CLM bit for the current line is to be asserted in a subsequent cycle. The first condition is met when one of N lines preceding the current line is indicated as not extended or its corresponding CLM bit is asserted. The second condition is met when all intervening lines each have an isolated match with one of the N beats in the current cycle.

### BACKGROUND

### Field

This disclosure relates generally to memories, and more specifically, to a ternary content addressable memory (TCAM) having variable size entries.

### Related Art

Content addressable memories (CAMs) are commonly used for efficient searching in high-speed applications, such as in networking devices. In one example, a CAM includes a number of lines, in which each line corresponds to an entry of the CAM. Look-up data is compared against the stored data in each line of the CAM and the index of the matching data is returned. In a binary CAM, each line of the CAM stores values including only binary bits of ones and zeros. However, a ternary CAM (TCAM) allows for a third state of X or “don't care”, in which each line of the TCAM stores values including ones, zeros, and don't cares. Each stored value in a TCAM may be referred to as a ternary value, in which, in one implementation, each ternary value is stored as two binary bits, in which one of the two binary bits is a mask bit which indicates whether or not the value of the other binary bit is a don't care. If a binary bit is indicated as a don't care, then either a one or a zero matches the bit value, therefore the use of TCAMs allow for increased flexibility with searches. Further flexibility is added by allowing a TCAM to have variable size entries, in which entries of a same TCAM can have different sizes and each entry is capable of spanning multiple lines. However, this increases the time to find matches within the TCAM as subsets of the look-up data bits must be presented for comparison over multiple cycles, therefore, a need exists for improved comparison efficiency with a TCAM implementing variable size entries.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in block diagram form, a TCAM system, in accordance with an embodiment of the present invention.

FIG. 2 illustrates, in partial schematic and partial block diagram form, a line and corresponding line circuitry of TCAM 100 of FIG. 1, the line circuitry having comparison circuitry and prerequisite determination circuitry, in accordance with an embodiment of the present invention.

FIG. 3 illustrates, in block diagram form, a more detailed view of the comparison circuitry of FIG. 2, in accordance with an embodiment of the present invention.

FIG. 4 illustrates, in schematic form, a more detailed view of the prerequisite determination circuitry of FIG. 2, in accordance with an embodiment of the present invention.

FIG. 5 illustrates, in partial block diagram and partial schematic form, further details of the line circuitries of a portion of TCAM 100, in accordance with one embodiment of the present invention.

### DETAILED DESCRIPTION

In one aspect, a TCAM includes a plurality of lines, in which the plurality of lines are configured to store up to half as many entries. The TCAM is configured such that each of the entries spans two or more lines of the TCAM. In one embodiment, each line of the TCAM is configured to store a ternary value as well as an extension bit which indicates whether the corresponding entry expands to the next line of the TCAM (i.e. whether it also includes the following line). For a search operation (i.e. look-up operation) in the TCAM, a look-up key is provided to the TCAM in predefined uniformly sized portions (referred to as beats) and an entry is considered a matching entry only if every line corresponding to the entry has matched with a corresponding portion of the look-up key. In order to improve search efficiency, N compare lanes (in which N is an integer greater than or equal to two) are provided to a TCAM such that multiple portions of the look-up key can be presented to the TCAM for comparison to multiple lines of an entry in parallel in each clock cycle. For example, each look-up key presented to the TCAM can be presented as groups of up to N input beats on the N compare lanes, each having a look-up value and an associated beat value. Since it is possible for a TCAM entry to span more than N lines, an entry match can be determined based on line matches which occurred in previous clock cycles as well as the current clock cycle.

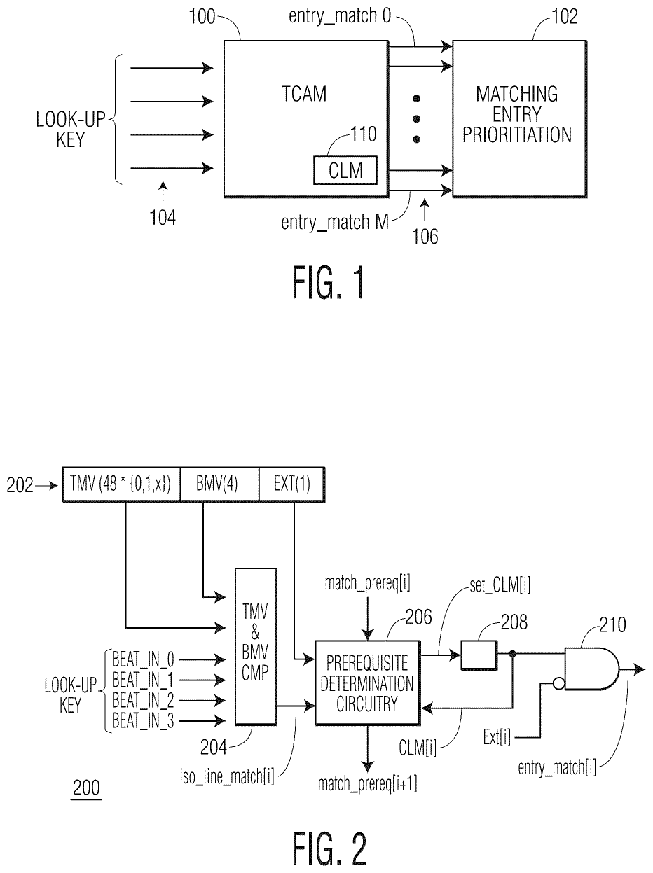

FIG. 1 illustrates, in block diagram form, a TCAM 100 coupled to a set of input lanes 104 and configured to provide a set of match entry indicators 106 to matching entry prioritization circuit 102, in accordance with an embodiment of the present invention. TCAM 100 includes Y lines, in which Y is an integer greater than or equal to two, in which each line is configured to store a ternary match value (TMV), a beat match value (BMV), and a corresponding extension (Ext) bit. The Y lines of TCAM 100 are configured to store up to Y/2 entries, in which each entry of TCAM 100 spans at least two lines up to a maximum number of lines, in which the corresponding extension bit of the last line of an entry is set to a logic level zero, indicating it is the last line of the entry, while the corresponding extension bits of the other lines of the entry are each set to a logic level one, indicating that the entry continues by spanning the next line. The extension bit may be referred to as an extension value, and, in alternate embodiments, may be implemented with more than one bit.

In one embodiment, each line of TCAM 100 belongs to a multiple-line entry of TCAM 100 and stores a TMV having 48 symbols, in which each symbol can be a logical one, logical zero, or a don't care. Each symbol of a ternary value can be implemented as two binary bits, in which each line of TCAM 100 is configured to store 96 binary bit values corresponding to the 48-symbol TMV. In one embodiment, each (multiple-line) entry of TCAM 100 includes at least two lines, up to a maximum of 14 contiguous lines (in which all lines of an entry are stored in logically sequential lines of the TCAM). Therefore, in this embodiment, each line of TCAM 100 includes a Ext bit as well as a 4-bit BMV corresponding to the 48-symbol TMV for a corresponding entry. The 4-bit BMV identifies the beat (i.e. portion) of the corresponding entry to which the 48-symbol TMV corresponds. (That is, the 4-bit BMV identifies the beat of the look-up key that the TMV of the line must match in order for a corresponding entry to match.) Since each entry can include up to 14 lines (and, as will be described below, each look-up key can include up to 14 beats), the 4-bits identify a binary value between 1 and 14 (e.g. 0b0001 0b1110, in which a “0b” preceding a value indicates a binary value). In one embodiment, a BMV value of zero (e.g. 0b0000) for a line indicates that the line is not in use (and thus will never result in a match with an input beat). As described above, when the corresponding Ext bit is a 0b1, the current entry extends to (i.e. also includes) the next line, but when the corresponding Ext bit is a 0b0, the corresponding line is the last line of the current entry (i.e. the next line is not part of the current entry). In one embodiment, the corresponding BMV of the first line of each entry is set to 0b0001, and the corresponding BMVs of the lines of an entry increment in value with each subsequent line of the entry (although the corresponding BMVs of the entry need not be contiguous). In alternate embodiments, the BMV values in TCAM 100 may include more or fewer bits, depending on a maximum number of beats or lines allowed per entry.

In one embodiment, for each search operation, a look-up key is provided to TCAM 100 as a series of beats (i.e. a series of predefined uniformly sized portions), each beat including a corresponding look-up value and beat value. In one embodiment, the look-up key may correspond to extracted fields of a received communication packet. In the embodiments herein, it is assumed that the look-up key includes a maximum of 672 bits (max symbols per line*max number of lines=48*14=672) which can be separated into a maximum of 14 beats. Each beat presented includes a line-width (e.g. 48-bit) look-up value corresponding to a 48-bit portion of the look-up key as well as a corresponding beat value which identifies the beat of the look-up key to which the look-up value corresponds. In this example, each beat value is a 4-bit binary value, capable of distinguishing between the 14 beats. Therefore, for each beat of a look-up key received by TCAM 100, a 48-bit look-up value and a corresponding 4-bit beat value is received. Note that the beat values for the beats of a look-up key are provided in increasing value (although they need not be contiguous in value). Although the example values provided above for the lines and entries of TCAM 100 and for the look-up key can differ based on the implementation, for the examples below, the values provided above will be used in describing search operations of TCAM 100.

For a search operation on a received look-up key, TCAM 100 determines a matching entry only if all lines of the entry in TCAM 100 match corresponding beats of the look-up key. Each line of TCAM 100 includes comparison logic, as known in the art, which determines whether a received beat matches the line, resulting in a line match (i.e. an isolated line match). A line of TCAM 100 matches a beat of the look-up key if both the 4-bit beat value of the look-up key matches the BMV of the line and the 48-bit look-up value of the look-up key matches the 48-symbol TMV of the line (in which, as described above, a don't care value of a TMV symbol matches a corresponding bit value of the look-up value, regardless of whether the corresponding bit value is a one or zero). Therefore, for an entry to match a look-up key, each line of the entry must match a corresponding beat (i.e. portion) of the look-up key. In one embodiment, TCAM 100 includes a cumulative line match register (CLM) 110, including one bit for each line of TCAM 100, which is used to keep track of cumulative matches over a series of clock cycles of the search operation, in which the cumulative register is cleared to zero before each search operation. An asserted CLM bit for a line of TCAM 200 indicates that an isolated match of the line has previously occurred and that the isolated match is also considered a cumulative match for the entry in which, when all lines of an entry cumulatively match, an entry match is indicated. (Note that a cumulative match of the last line of an entry is a sufficient indication of an entry match as it can only occur when all preceding lines of the entry have also achieved a cumulative match.)

For example, in the case in which one input beat of the look-up key is provided to TCAM 100 each clock cycle (e.g. in which TCAM 100 is coupled to only one of input lanes 104), when the input beat matches a line of TCAM 100, the corresponding bit in CLM 110 is asserted to a logic level one. So long as the corresponding Ext bit of matching lines over subsequent clock cycles is a logic level one, no entry match is indicated. However, when the corresponding Ext bit of a matching line is a logic level zero (indicating the last line of an entry), an entry match is indicated only if the corresponding bits of CLM 110 for all lines of the entry preceding the last line have already been asserted. If this is the case (i.e. if this prerequisite is met), then each line of the entry has been matched to the corresponding beats of the look-up key. This prerequisite check can be accomplished simply by, upon detecting a line latch, checking the cumulative match bit of the preceding line, in which an entry match is indicated if that cumulative match bit is asserted (because the input beats of a look-up key are provided with increasing beat values and the lines of an entry are stored with increasing BMVs).

In one embodiment, each line of TCAM 100 can be referenced using a unique index value, in which the index values define which lines logically precede and succeed each other in TCAM 100. The index values can be used to access each line, in turn, to determine isolated line matches. After determining that a line matches in isolation of other lines (i.e. an isolated line match), it can be determined whether the line match also results in an entry match. If so, the index value of the matching entry (e.g. the index value of the line of the last line of the entry) is output by TCAM 100. Therefore, TCAM 100 provides the set of entry match indicators, one for each line of TCAM 100, to matching entry prioritization, in which the indices of the matching entries (those lines whose corresponding entry match indicators are asserted) can be used to select a highest priority entry match, using any known prioritization scheme. (Although illustrated within TCAM 100, CLM 110 may be located outside of TCAM 100. Also, register 110 may be implemented with any type of storage circuitry.)

Note that in the case in which TCAM 100 receives one input lane such that only one input beat is provided per cycle but the look-up key can have up to 14 beats, up to 14 cycles are required to determine an entry match. For example, on a particular input beat of a search operation, an isolated line match may be determined which may immediately determine an entry match (if it were the last line of the entry), but all beats of a look-up key still need to be presented to determine whether other entries (with dependencies upon yet to be presented beats of the look-up key) will match as they may result in a higher priority matching entry. Requiring up to 14 clock cycles per entry match, though, may not be an acceptable performance for the search operation.

Therefore, in one embodiment, more than one beat of the look-up key is provided each clock cycle to TCAM 100 for parallel comparisons. In this embodiment, parallel compare logic is implemented within each line of TCAM 100 to perform multiple (N) comparisons per each line of TCAM 100, in which N is an integer value greater than or equal to two. As illustrated in FIG. 1, N=4 such that TCAM 100 is coupled to receive a set of 4 input lanes (also referred to as compare lanes). In this manner, 4 beats of the look-up key (rather than just one) can be processed in each clock cycle of a search operation, thus improving efficiency. However, since up to 4 beats are provided in each clock cycle, upon a line match, it is not sufficient to check stored state of the cumulative match bit of a preceding line (which would have become asserted in a previous clock cycle) because some of the input beats could be matching within the same current clock cycle. Therefore, upon a line match, not only do cumulative match bits of CLM 110 for previous lines need to be checked to determine whether an entry match occurred, but the results of any isolated line matches occurring in the current clock cycle may also need to be checked to properly determine whether an entry match occurred. Although the examples herein will be described in reference to N=4, the descriptions can apply to any value of N (in which N>=2).

FIG. 2 illustrates, in partial block diagram and partial schematic form, line circuitry 200, in accordance with an embodiment of the present invention, in which line circuitry 200 may correspond to any line of TCAM 100, in which each line of TCAM 100 has analogous line circuitry. In the descriptions herein, index value “i” is used to reference the current line of TCAM 100, in which “i−1” refers to the immediately preceding line to line i, line “i−2” to the line which is 2 lines back from line i, etc. Therefore, line circuitry 200 of FIG. 2 is coupled to line 202 of TCAM 100, which corresponds to line i of TCAM 100. Note that line 202 may be considered to be a storage component of line circuitry 200, in which the remaining circuitry of FIG. 2 may be considered as match circuitry or comparison circuitry for line 202.

In the illustrated embodiment, line circuitry 200 includes BMV and TMV comparison circuitry 204 which is coupled to access the 48-symbol TMV portion and the 4-bit BMV portion of line 202. Comparison circuitry 204 receives up to 4 active input beats (portions) of the look-up key as BEAT_IN_0, BEAT_IN_1, BEAT_IN_2, and BEAT_IN_3, in which each active input beat includes a look-up value of 48 bits and a corresponding non-zero beat value of 4 bits. (Note that a beat value of zero indicates an unused beat which is needed in the case that the total number of beats in a look-up key is not an integer multiple of N.) Comparison circuitry 204 outputs an isolated line match indicator corresponding to line 202 (iso_line_match[i]), which is asserted to a logic level one only if both the look-up value and beat value pair of any of the 4 input beats match the BMV and TMV of line 202, and negated to a logic level zero otherwise. As explained above, having an isolated line match is not sufficient for an entry match, therefore line circuitry 200 includes prerequisite (prereq) determination circuitry 206 to determine whether a set of prerequisites have been met to further indicate if the current isolated match is sufficient to indicate a cumulative match by setting the corresponding CLM bit 208 of CLM 110 (in which bit 208 is a one-bit portion of CLM 110 which can be implemented as a flop). If the set of prerequisites have been met based on information from a previous line i−1 (resulting in the match_prereq of the current line (match_prereq[i]) being asserted), and the current line has matched (indicated by iso_line_match[i]), then set_CLM[i] is asserted so as to set the value of CLM bit 208 to a logic level one at the next clock cycle. Once CLM bit 208 is asserted and the corresponding Ext bit also indicates line 202 is the last line of the entry (if Ext=0), then entry match detection circuitry (illustrated as AND gate 210) asserts entry_match[i] to a logic level one, indicating a matching entry has been detected. Prereq determination circuitry 206 also provides a match_prereq indicator (match_prereq[i+1]) to the prereq determination circuity of the line subsequent to line 202 (e.g. to line i+1).

Note that, since the size of entries stored within TCAM 100 is variable, from as small as two lines to as many as 14 lines, some lines require more time to result in an entry match. Therefore, in one embodiment, sufficient time is provided to allow a look-up key to result in all appropriate entry matches before matching entry prioritization uses the entry_match values 0-M to determine a highest priority matching entry. In one embodiment, the number of entry_matches, M+1, may correspond to the total number of lines of TCAM 100 (e.g. Y lines). Further, since TCAM 100 is a ternary CAM, multiple entries can match in response to a particular look-up key. Therefore, the time it takes to provide a highest priority matching entry depends on how long it takes to process (e.g. perform a search operation on) the longest look-up key.

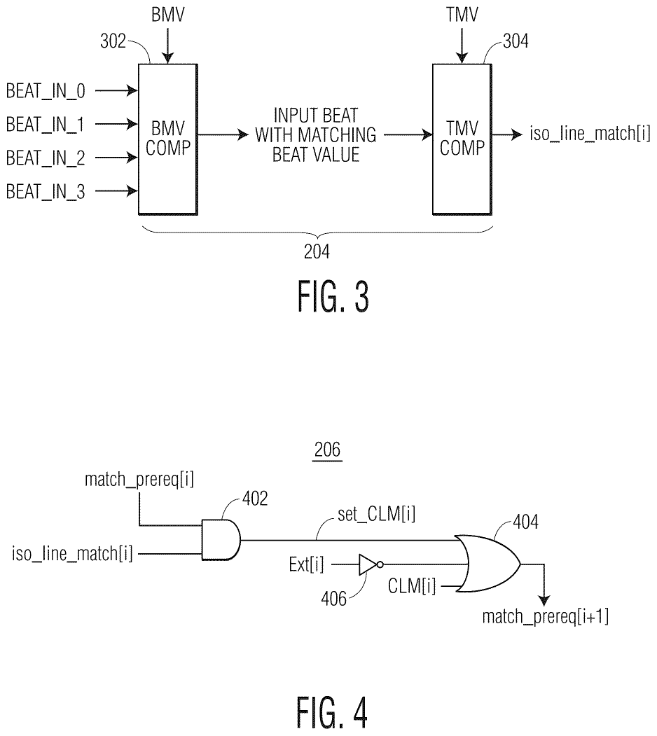

FIG. 3 illustrates, in block diagram form, an implementation of comparison circuitry 204, in accordance with one embodiment of the present invention. As illustrated in FIG. 3, comparison circuitry 204 may be separated into BMV comparison circuitry 302 and TMV comparison circuitry 304. In this embodiment, the beat value of each of the 4 inputs beats can be compared to the BMV of line 202, and since there can only be at most one matching input beat, the input beat whose beat value matches the BMV is directed to TMV comparison circuitry 304. TMV comparison circuitry 304 therefore performs a single comparison between the look-up value of the input beat with the matching beat value and the TMV of line 202. If these match, then iso_line_match[i] is asserted. In this manner, while BMV comparison circuitry 302 performs 4 comparisons (one for each input compare lane), TMV comparison circuitry 304 only performs one comparison, which may help simplify circuitry in each line of TCAM 100.

FIG. 4 illustrates, in schematic form, a more detailed view of prereq determination circuitry 206 of FIG. 2, including AND gate 402, inverter 406, and OR gate 404, in accordance with one embodiment of the present invention. Prereq determination circuity 206 receives match_prereq[i] for the current line from the line preceding line 202, in which match_prereq[i] is provided as a first input to AND gate 402 and iso_line_match[i] is provided as a second input to AND gate 402, and AND gate 402 provides set_CLM[i] at its output. Therefore, if both match_prereq[i] and iso_line_match[i] are asserted (indicating the appropriate prereq was met in addition to detecting an isolated match of line 202), then AND gate 402 asserts set_CLM[i] is to a logic level one, which will be stored at the next clock cycle in bit 208 of CLM 110. The output of AND gate 402 is coupled to provide set_CLM[i] to a first input of OR gate 404, Ext[i] is provided via inverter 406 to a second input of OR gate 404, and CLM[i] (corresponding to the bit value stored in bit 208, which was captured in a previous clock cycle) is provided to a third input of OR gate 404. An output of OR gate 404 provides match_prereq[i+1] to the next line of TCAM 100. Therefore, if an isolated line match has occurred and the prerequisites have been met to result in a cumulative match so as to set CLM bit 208, match_prereq[i+1] is asserted. Further, if Ext of line 202 is a zero, indicating that it is the last line of the entry (and thus has no effect on subsequent entries) or if bit 208 has already been set to one in a previous clock cycle, match_prereq[i+1] is also asserted.

Therefore, note that the assertion of set_CLM[i] indicates occurrence of a line match in the current clock cycle, while CLM[i] (stored in bit 208) corresponds to the value of bit 208 which was captured in a previous clock cycle. For an entry_match to occur, note that all beats of the look-up key have to match an entry of TCAM 100, therefore, if an isolated match occurs, its possible that one or more beats of the look-up key matched in previous clock cycles and that one or more of the beats can be matching in the current clock cycle. As seen in the embodiment of FIG. 4, the isolated line matches of the lines are propagated through combinational logic (e.g. AND and OR gates analogous to AND gate 402 and OR gate 404) to properly set the match prerequisites, without being latched. This may create too long of a path to propagate all isolated line matches through each line of TCAM 100 to properly determine whether any of the input beats match in the current clock cycle. However, since it is known how many beats are received in each clock cycle (e.g. N=4 in the illustrated embodiments), each with increasing beat values, it can be assumed that the CLM bits of the N lines prior to i, (and the corresponding EXT bits of those lines) as well as the isolated match indicators of the previous N−1 lines is sufficient to determine whether the prerequisites for indicating a cumulative match for a current line i (i.e. for asserting set_CLM[i]) have been met. Therefore, the prereq determination circuitry for each line can be implemented in such a way as to limit a path of combinational logic between flops to determine relevant isolated matches within a current clock cycle.

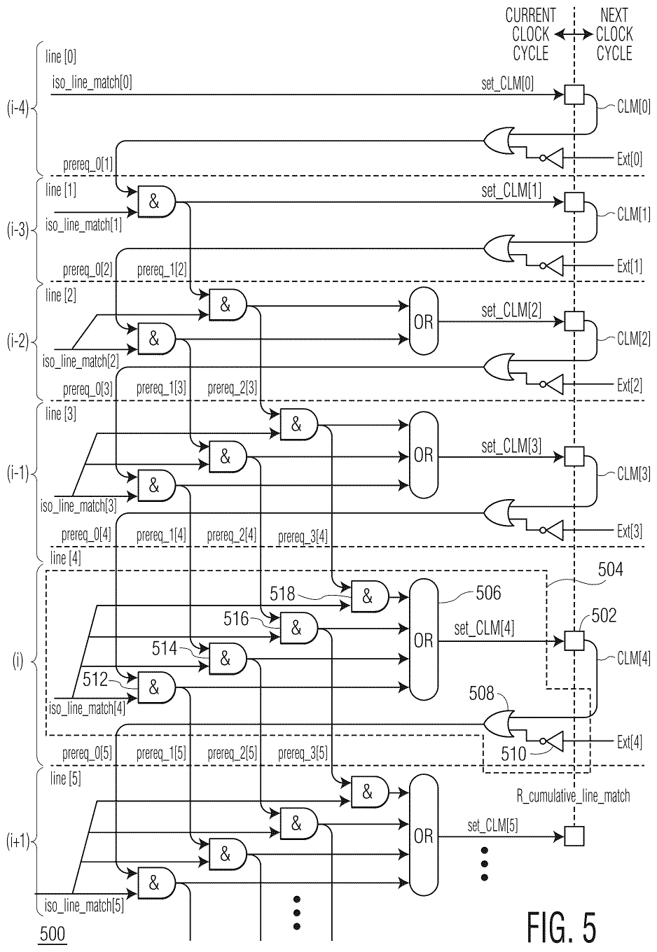

FIG. 5 illustrates, in partial block diagram and partial schematic form, an implementation of prereq determination circuitry for each of a first set of lines of TCAM 100, line[0]-line[5], in accordance with an embodiment of the present invention. For each of explanation, FIG. 5 will be described in reference to prereq determination circuitry 504 corresponding to the 5^{th} line of TCAM 100, line[4]. The description will be from the perspective that the “current line” being evaluated (with the current index value i) corresponds to line[4]. Therefore, the line with the index value i−1 corresponds to the immediately preceding line, line[3], the line with index value i−2 corresponds to the line that is two lines immediately preceding the current line, line[2], and the line with the index value i−3 corresponds to line[1], and the line with index value i−4 corresponds to line[0]. Note that, as explained above, each line of TCAM 100 is evaluated or processed, in turn, for i=0 up to the total number of lines in TCAM 100. During the processing of each line, it is determined whether an isolated line match occurs, and if so, whether the corresponding CLM bit should be asserted (to indicate a cumulative match). Therefore, for each line, the corresponding iso_line_match (iso_line_match[i]) is provided which indicates whether one of the input beats matched the BMV and TMV of the corresponding line. Note that, for each line, the stored CLM bit and corresponding Ext bit can then be used by entry match detection circuitry to determine whether an entry match occurs (as illustrated, for example, by AND gate 210 in FIG. 2).

For the illustrated embodiment of FIGS. 5, 4 input beats are received within a current clock cycle, in which, for the current line being evaluated (line[4], in which i=4), iso_line_match[4] is provided to prereq determination circuitry 504 of line[4] (in which iso_line_match[4] indicates whether one of the 4 input beats matched the BMV and TMV of the corresponding line, line[4], of TCAM 100). Prereq determination circuitry 504 also receives prereq information from previous lines, in which the prereq information is separated into 4 separate portions of information: prereq_0, prereq_1, prereq_2, and prereq_3. This prereq information is received by the corresponding prereq determination circuitry of each line, except that for line[1], only prereq_0 is received, and for line [2], only prereq_0 and prereq_1 are received, and for line 3, only prereq_0, prereq_1, and prereq_2 are received because line[0] corresponds to the first line of TCAM 100. However, all 4 portions of the prereq information is received for line[4] and beyond. For line[4], these portions of prereq information correspond to prereq_0[4], prereq_1[4], prereq_2[4], and prereq_3[4]. Each line also has a corresponding bit of CLM 110, illustrated as a small box which may be implemented as a flop and may therefore be referred to as either a “bit” or a “flop”. For line[4], bit 502 corresponds to the corresponding bit of CLM 110 for this line and therefore provides CLM[4]. An input of bit 502 receives set_CLM[4]. Note that the logic prior to flop 502 propagates its values during the current clock cycle, while the value in flop 502 is captured for use in subsequent clock cycles until the current search operation is complete (as labeled at the top of FIG. 5.) The prereq determination circuitry of each line also receives a corresponding Ext bit. For line[4], prereq determination circuitry 504 receives Ext[4] (from line[4] of TCAM 100).

Referring to line[4], prereq determination circuitry 504 includes AND gates 512, 514, 516, and 518, a 4-input OR gate 506, and inverter 510, and a 2-input OR gate 508. Each of AND gates 512, 514, 516, and 518 receive a corresponding portion of the prereq information as well as iso_line_match[4]. A first AND gate, AND gate 512, is coupled to receive prereq_0[4] at a first input and iso_line_match[4] at a second input. A second AND gate, AND gate 514, is coupled to receive prereq_1[4] at a first input and iso_line_match[4] at a second input. A third AND gate, AND gate 516, is coupled to receive prereq_2[4] at a first input and iso_line_match[4] at a second input. A fourth AND gate, AND gate 518, is coupled to receive prereq_3[4] at a first input and iso_line_match[4] at a second input. An output of each of the AND gates is provided to a corresponding input of 4-input OR gate 506. An output of OR gate 506 provides set_CLM[4] to selectively assert CLM[4]. OR gate 508 has a first input coupled to receive CLM[4] and a second input is coupled to receive Ext[4] via inverter 510 (thus receiving ! Ext[4], in which the “!” indicates NOT or the inverse of the following value). Note that an output of OR gate 508 provides prereq_0 to a subsequent line (e.g. prereq_0[5]).

The prereq portions (prereq_0-prereq_3) received by the prereq determination circuitry of each line, when logically ORed together, provide the same information as provided by match_prereq[i] described in reference to FIG. 2. However, the implementation of FIG. 5 avoids a long combinational path which may cause problems in a design. In the case in which N input beats are received, for any given line, an isolated match with one of the N beats can be considered a cumulative match (resulting in assertion of the corresponding CLM bit) if both of the following conditions, A and B, are met (i.e. true): condition A) one of the N preceding lines is not extended or has a registered cumulative line match (i.e. its corresponding CLM bit is asserted) and condition B) all intervening lines also have an isolated match (i.e. each matches one of the N input beats). In this case, the “intervening lines” refer to those lines between the line which met the first condition and the current line. Note that each match on these intervening lines would be occurring with one of the N input beats in the current clock cycle. In the example for 4 compare lanes (N=4), the match_prereq for each line i can be expressed as follows:

match_prereq[i]=(!Ext[i−1]) OR CLM[i−1]) OR

(!Ext[i−2] OR CLM[i−2]) AND iso_line_match[i−1] OR

(!Ext[i−3] OR CLM[i−3]) AND iso_line_match[i−2] AND iso_line_match[i−1] OR

(!Ext[i−4] OR CLM[i−4]) AND iso_line_match[i−3] AND iso_line_match[i−2] AND iso_line_match[i−1] (1)

The elements in the above equation (Eq. 1) for match_prereq[i] can be separated into separate portions, as separated by the bolded ORs of the equation, in which match_prereq[i]=prereq_0[i] OR prereq_1[i] OR prereq_1[i] OR prereq_3, in which:

prereq_0[i]=!Ext[i−1]) OR CLM[i−1] (2)

prereq_1[i]=(!Ext[i−2] OR CLM[i−2]) AND iso_line_match[i−1] (3)

prereq_2[i]=(!Ext[i−3] OR CLM[i−3]) AND iso_line_match[i−2] AND iso_line_match[i−1] (4)

prereq_3[i]=(!Ext[i−4] OR CLM[i−4]) AND iso_line_match[i−3] AND iso_line_match[i−2] AND iso_line_match[i−1] (5)

Since N=4, it is known that any line in a group of 4 lines in TCAM 100 can be marked as a last line of the entry with Ext=0. As seen above, with the set of equations (Eq. 2-Eq.5), the portion of each equation which includes “!Ext[x] OR CLM[x]” corresponds to condition A in which one of the N preceding lines is not extended or has a registered cumulative line match (indicating that the line already matched in a previous clock cycle). The portion of each equation which ANDs together iso_line_matches of one or more previous lines corresponds to condition B in which all intervening lines also have an isolated match.

Referring now to lines[1-4] of FIG. 5 as an example, within a current clock cycle in which line[4] is currently being processed, if an isolated match of one of the 4 input beats occurs with line[4] (such that iso_line_match[4]=1), the isolated match is considered a cumulative match (in which set_CLM[4] is asserted) only if the prerequisite conditions are met. (Further, note that the isolated match may also result in an entry match if the corresponding Ext bit, Ext[4], indicates it is the last line of an entry.)

For example, with line[4] being processed, if line[3] (the previous line at i−1) is not extended (meaning it is not part of the same entry as the current line and therefore does not affect the same entry as the current line) or line[3] already has its corresponding CLM bit asserted (meaning line[3] already had a line match in a previous clock cycle), then set_CLM[4] is asserted to set the corresponding CLM bit of the current line. That is, if Ext[i−1] =0 or CLM[i−1]=1, then prereq_0=1, resulting in match_prereq[4]=1. Note that, in this example, condition A is met with “Ext[i−1]=0 OR CLM[i−1]=1,” and condition B does not matter because there are no intervening lines between the line that met condition A, e.g. line[3], and the current line, e.g. line[4].

As another example, with line[4] being processed, if line[2] (a previous line two lines before the current line, at i−2) is not extended or line[2] already has its corresponding CLM bit asserted (meaning line[2] already had a line match in a previous clock cycle), then condition A is met. To meet condition B, all intervening lines (e.g. line[3] only) has to also match one of the 4 input beats. Therefore, if a match occurs in the current clock cycle such that iso_line_match[3] is also asserted to a one, then condition B is also met. That is, if Ext[i−2]=0 or CLM[i−2]=1 as well as iso_line_match[3]=1, then prereq_1=1, resulting in match_prereq[4]=1.

As another example, with line[4] being processed, if line[1] (a previous line three lines before the current line, at i−3) is not extended or line[1] already has its corresponding CLM bit asserted, then condition A is met. Condition B is met only if each of iso_line_match[2] and iso_line_match[3] (corresponding to the intervening lines) also match in the current clock cycle. That is, if Ext[i−3]=0 or CLM[i−3]=1 as well as iso_line_match[3]=iso_line_match[2]=1, then prereq_2=1, resulting in match_prereq[4]=1.

As another example, with line[4] being processed, if line[0] (a previous line four lines before the current line, at i−4) is not extended or line[0] already has its corresponding CLM bit asserted, then condition A is met. Condition B is met only if each of iso_line_match[1], iso_line_match[2], and iso_line_match[3] (corresponding to the intervening lines) also match in the current clock cycle. That is, if Ext[i−4]=0 or CLM[i−4]=1 as well as iso_line_match[3]=iso_line_match[2]=iso_line_match[1]=1, then prereq_3=1, resulting in match_prereq[4]=1.

Therefore, in processing line[4], match_prereq[4] can be asserted in response to any of the 4 prereq portions (which can “look” as far back as line[i−4]), and set_CLM[4] is asserted only if iso_line_match[4] and match_prereq[4] are both asserted. Note that it is not necessary for the prereq determination circuitry to further look back to line i−5, in general, to determine if the prerequisites are met because since N=4, it is known that only up to N lines can match in the current clock cycle. Therefore, going back to a line that is N lines prior to the current line is sufficient to determine if a match occurred in a previous cycle (or if it is not an extended line), and there can only be, at most, N−1 (e.g. 3) intervening lines between the current line and the line which met the first condition. For this reason, the prerequisite information needed by the prereq determination circuitry of any line[i] to determine whether or not both prerequisite conditions A and B are met only require inputs from the previous 4 lines (line[i−1], line[i−2], line[i−3], and line[i−4]), as seen by Eq. 1 for match_prereq[i] above.

Note that in alternate embodiments, the digital (e.g. combinational) logic implemented by the prereq determination circuitry of each line can be implemented differently to accomplish the function of determining match_prereq[i] (e.g. to determine if conditions A and B are met), in which the logic of FIG. 5, explained in reference to prereq determination circuitry 504 of line[4], is only one example. By implementing the logic as illustrated in FIG. 5 rather than as illustrated in FIG. 4, though, it can be seen that the worst case propagation for a single through a series of gates to provide match information within a current clock cycle is limited by using the knowledge that only N beats are received each clock cycle and only up to N matches can occur in the current clock cycle. For example, referring to line[4] as the current line being processed, in the case in which prereq_4[4] is met, in which each of three intervening lines (line[1], line[2], and line[3]) also have to match, the worst case delay path (from flop to flop) is 7 gates (e.g. the inverter and OR gate analogous to inverter 510 and OR 508 for line[0], the first AND gate of line[1], the second AND gate of line[2], the third AND gate of line[3], the fourth AND gate of line[4], and the OR gate analogous to OR gate 506).

Note that TCAM cells capable of storing ternary symbols (e.g. two bits) to provide the values of 0,1, or “don't care” can be implemented as known in the art. The max number of ternary symbols stored per line can be more or less than 48 and the beat values can include more or fewer bits, depending on the max size (i.e. max number of beats) of the look-up key. TCAM may be configured such that each entry spans up to a different number of maximum lines, more or fewer than 14. In an alternate embodiment, an entry can either be one line or span more than one line. The maximum value of the look-up key can therefore also be more or fewer than 14 beats. Similarly, while many of the example above were described in reference to TCAM 100 having 4 input compare lines for 4 beats, in alternate embodiments, N can be any value in which the prerequisite determination circuitry of each line would be configured to receive prerequisite information from at least the previous N line to determine whether an isolated match results in a cumulative match. Also, similar to the logic of the prereq determination circuitries (e.g. 206, 504, etc.), the logic for the comparison circuitries (e.g. 204, 302, 304) and match determination circuitry (e.g. 210) can also be implemented using a different combination of logic gates.

Therefore, by now it can be understand how multiple compare lanes for a TCAM can be used to improve the efficiency of search operations. The TCAM includes a plurality of lines, in which each line stores a corresponding ternary match value, beat match value, and extension bit. The TCAM can store variable length entries in which each entry may span two or more contiguous lines of the TCAM. Therefore, each look-up key provided to TCAM for a search operation may include as many bits as the maximum entry length allows. In one embodiment, the look-up key is provided as N multiple beats or portions to the TCAM (each beat having a look-up value and corresponding beat value), in which, for each line of the TCAM, N comparisons can be performed each clock cycle. In one aspect, the corresponding beat values of the N multiple beats are compared to the beat match value of each line, in which the ternary match value of a line is only compared to the look-up value of a matching beat. In processing each line of the TCAM in turn, it is determined whether a matching beat (which matches both the ternary match value and beat match value of the line) is further considered to be a cumulative match by determining if prerequisite conditions have been met. In one embodiment, prerequisite information from the N lines previous to the matching line are used to determine if the prerequisite conditions have been met. If so, then a corresponding cumulative match bit corresponding to the line is asserted. Entry matches are then detected for those lines whose cumulative bits are set and which represent a last line of an entry in the TCAM. By presenting multiple beats to the TCAM each clock cycle, improved efficiency of search operations may be achieved, as compared, for example, to presenting a single beat each clock cycle.

As used herein, the term “bus” is used to refer to a plurality of signals or conductors which may be used to transfer one or more various types of information, such as data, addresses, control, or status. The conductors as discussed herein may be illustrated or described in reference to being a single conductor, a plurality of conductors, unidirectional conductors, or bidirectional conductors. However, different embodiments may vary the implementation of the conductors. For example, separate unidirectional conductors may be used rather than bidirectional conductors and vice versa. Also, plurality of conductors may be replaced with a single conductor that transfers multiple signals serially or in a time multiplexed manner. Likewise, single conductors carrying multiple signals may be separated out into various different conductors carrying subsets of these signals. Therefore, many options exist for transferring signals.

The terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Each signal described herein may be designed as positive or negative logic, where negative logic can be indicated by a bar over the signal name or an asterisk (*) following the name. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Brackets are used herein to indicate the conductors of a bus or the bit locations of a value or the index value of a circuit element. For example, “bus 60 [7:0]” or “conductors [7:0] of bus 60” indicates the eight lower order conductors of bus 60, and “address bits [7:0]” or “ADDRESS [7:0]” indicates the eight lower order bits of an address value. For example, register[5] indicates bit 5 of the register, and line[5] corresponds to the line indexed by the index value of 5. The symbol “$” or “0 b” preceding a number indicates that the number is represented in its hexadecimal or base sixteen form. The symbol “%” preceding a number indicates that the number is represented in its binary or base two form.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Some of the above embodiments, as applicable, may be implemented using a variety of different information processing systems. For example, although FIG. 1 and the discussion thereof describe an exemplary memory system architecture, this exemplary architecture is presented merely to provide a useful reference in discussing various aspects of the invention. Of course, the description of the architecture has been simplified for purposes of discussion, and it is just one of many different types of appropriate architectures that may be used in accordance with the invention. Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Also for example, in one embodiment, the illustrated elements of the memory system of FIG. 1 are circuitry located on a single integrated circuit or within a same device. Alternatively, the system may include any number of separate integrated circuits or separate devices interconnected with each other.

Furthermore, those skilled in the art will recognize that boundaries between the functionality of the above described operations merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the invention is described herein with reference to specific embodiments, various modifications and changes can be made without departing from the scope of the present invention as set forth in the claims below. For example, different memory types may be used to implement TCAM 100 and different circuitry may be used to implement the ternary values of TCAM 100. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention. Note that any of the aspects below can be used in any combination with each other and with any of the disclosed embodiments.

In an embodiment, an integrated circuit includes a ternary content addressable memory (TCAM) having a plurality of lines and a plurality of entries, in which each entry is formed by at least two contiguous lines of the plurality of lines, wherein each line is configured to store a corresponding extension value which indicates whether or not the line extends to a next contiguous line in forming an entry of the TCAM; and input compare lanes coupled to receive N beats in a current clock cycle, wherein the N beats correspond to N portions of a look-up key presented for a search operation in the TCAM, N being an integer greater than or equal to two. The TCAM includes storage circuitry configured to store a corresponding cumulative line match (CLM) bit for each line of the plurality of lines, wherein an asserted CLM bit indicates that an isolated line match for the line to which it corresponds has occurred in a previous clock cycle; and prerequisite determination circuitry for each line of the plurality of lines configured to, in response to an isolated line match of a current line in the TCAM with any one of the N beats and both a first condition and a second condition being met, indicate that the corresponding CLM bit for the current line is to be asserted in a subsequent clock cycle, wherein the first condition is met when one of N lines in the TCAM preceding the current line is indicated as not extended or its corresponding CLM bit is asserted and the second condition is met when all intervening lines between the one of the N preceding lines of the TCAM and the current line each have an isolated match with one of the N beats in the current clock cycle. In one aspect, each line of the plurality of lines is further configured to store a corresponding ternary match value (TMV) and a corresponding beat match value (BMV), and each beat of the N beats is configured to have a corresponding look-up value and a corresponding beat value. In a further aspect, an isolated line match of the current line occurs when any one of the N beats has a corresponding look-up value and corresponding beat value which matches the corresponding TMV and corresponding BMV of the current line. In yet a further aspect, each line of the plurality of line further includes BMV comparison circuitry configured to perform up to N comparisons to determine if a match occurs between the corresponding BMV of the current line and the corresponding beat value of any one of the N beats, and TMV comparison circuitry configured to determine if a match occurs between the corresponding TMV of the current line and the corresponding look-up value of a matching beat from the BMV comparison circuitry whose corresponding beat value matched the corresponding BMV of the current line. In another aspect, the look-up key is configured to be presented as a maximum number of beats to the TCAM, wherein N is less than the maximum number of beats, and, for each beat of the N beats, the corresponding beat value identifies which beat of the maximum number of beats to which the corresponding look-up value corresponds. In yet a further aspect, each entry of the plurality of entries is formed by a maximum number of lines of the TCAM, wherein the corresponding BMV of each line of the plurality of lines identifies which beat of the maximum number of beats to which the corresponding TMV corresponds. In another aspect, each of the corresponding TMVs include a set of symbols, each indicating one of a logical one, a logical zero, or a don't care and the look-up values of the N input beats include a set of bit values, each indicating a logical one or a logical zero, in which the set of bit values includes half as many bits as a number of symbols in the set of symbols. In another aspect of the above embodiment, the prerequisite determination circuitry for each line is configured to receive an isolated line match indicator which indicates whether a line match occurred with any one of the N beats and prerequisite information from each of N preceding lines, wherein the prerequisite determination circuitry uses the received prerequisite information from the N preceding lines to determine whether the first and second conditions are met. In a further aspect, the prerequisite determine circuitry for each line does not receive prerequisite information from lines preceding the N preceding lines. In another aspect, the TCAM further includes entry match determination circuitry for each line, coupled to receive the corresponding CLM bit and the corresponding extension value of the line, wherein the entry match determination circuitry indicates an entry match when the corresponding CLM bit is asserted and the corresponding extension value of the line indicates it is not extended. In yet another aspect of the above embodiment, the look-up key is parsed from a received communication packet.

In another embodiment, an integrated circuit includes a ternary content addressable memory (TCAM) having a plurality of lines and a plurality of entries, in which each entry is formed by at least two contiguous lines of the plurality of lines, wherein each line is configured to store a corresponding extension value which indicates whether the line is a last line of an entry of the TCAM or instead extends to a next contiguous line of the entry; and input compare lanes coupled to receive N beats in a current clock cycle, wherein the N beats correspond to N portions of a look-up key presented for a search operation in the TCAM, N being an integer greater than or equal to two. The TCAM includes storage circuitry configured to store a corresponding cumulative line match (CLM) bit for each line of the plurality of lines, wherein an asserted CLM bit indicates that an isolated line match for the line to which it corresponds has occurred in a previous clock cycle; and line circuitry for each line of the plurality of lines configured to, when an isolated line match of a current line of the plurality of lines with any one of the N beats occurs, determining an entry match for a corresponding entry when the corresponding extension value of the current line indicates it is the last line of the corresponding entry and all previous contiguous lines of the corresponding entry have matched in either previous clock cycles as indicated by corresponding CLM bits or in the current clock cycle with any of the N beats. In one aspect of the another embodiment, the line circuitry of each line includes prerequisite determination circuitry configured to receive prerequisite information from line circuitry of a previous line of the plurality of lines, and, in response to the isolated line match of the current line, when the prerequisite information indicates a match prerequisite has been met, indicate that the corresponding CLM bit for the current line is to be asserted in a subsequent clock cycle. In a further aspect, the prerequisite determination circuitry for each line provides prerequisite information to line circuitry of a subsequent line of the plurality of lines based on the prerequisite information received from line circuitry of the previous line, an isolated match indicator of the current line, the corresponding extension value of the current line, and the corresponding CLM bit for the current line. In another aspect, the prerequisite information is based at least in part on isolated line matches determined in the current clock cycle with any of the N input beats. In another aspect of the another embodiment, each line of the plurality of lines is further configured to store a corresponding ternary match value (TMV) and a corresponding beat match value (BMV), and each beat of the N beats is configured to have a corresponding look-up value and a corresponding beat value. In a further aspect, an isolated line match of the current line occurs when any one of the N beats has a corresponding look-up value and corresponding beat value which matches the corresponding TMV and corresponding BMV of the current line. In a further aspect, each line of the plurality of line further includes BMV comparison circuitry configured to perform up to N comparisons to determine if a match occurs between the corresponding BMV of the current line and the corresponding beat value of any one of the N beats, and TMV comparison circuitry configured to determine if a match occurs between the corresponding TMV of the current line and the corresponding look-up value of a matching beat from the BMV comparison circuitry whose corresponding beat value matched the corresponding BMV of the current line. In another further aspect, the look-up key is configured to be presented as a maximum number of beats to the TCAM, wherein N is less than the maximum number of beats, and, for each beat of the N beats, the corresponding beat value identifies which beat of the maximum number of beats to which the corresponding look-up value corresponds. In a further aspect, each entry of the plurality of entries is formed by a maximum number of lines of the TCAM, wherein the corresponding BMV of each line of the plurality of lines identifies which beat of the maximum number of beats to which the corresponding TMV corresponds.

What is claimed is:

1. An integrated circuit, comprising:
a ternary content addressable memory (TCAM) having a plurality of lines and a plurality of entries, in which each entry is formed by at least two contiguous lines of the plurality of lines, wherein each line is configured to store a corresponding extension value which indicates whether or not the line extends to a next contiguous line in forming an entry of the TCAM; and
input compare lanes coupled to receive N beats in a current clock cycle, wherein the N beats correspond to N portions of a look-up key presented for a search operation in the TCAM, N being an integer greater than or equal to two;
wherein the TCAM comprises:
storage circuitry configured to store a corresponding cumulative line match (CLM) bit for each line of the plurality of lines, wherein an asserted CLM bit indicates that an isolated line match for the line to which it corresponds has occurred in a previous clock cycle; and
prerequisite determination circuitry for each line of the plurality of lines configured to, in response to an isolated line match of a current line in the TCAM with any one of the N beats and both a first condition and a second condition being met, indicate that the corresponding CLM bit for the current line is to be asserted in a subsequent clock cycle, wherein the first condition is met when one of N lines in the TCAM preceding the current line is indicated as not extended or its corresponding CLM bit is asserted and the second condition is met when all intervening lines between the one of the N preceding lines of the TCAM and the current line each have an isolated match with one of the N beats in the current clock cycle.

2. The integrated circuit of claim 1, wherein each line of the plurality of lines is further configured to store a corresponding ternary match value (TMV) and a corresponding beat match value (BMV), and each beat of the N beats is configured to have a corresponding look-up value and a corresponding beat value.

3. The integrated circuit of claim 2, wherein an isolated line match of the current line occurs when any one of the N beats has a corresponding look-up value and corresponding beat value which matches the corresponding TMV and corresponding BMV of the current line.

4. The integrated circuit of claim 3, wherein each line of the plurality of line further comprises:
BMV comparison circuitry configured to perform up to N comparisons to determine if a match occurs between the corresponding BMV of the current line and the corresponding beat value of any one of the N beats, and
TMV comparison circuitry configured to determine if a match occurs between the corresponding TMV of the current line and the corresponding look-up value of a matching beat from the BMV comparison circuitry whose corresponding beat value matched the corresponding BMV of the current line.

5. The integrated circuit of claim 2, wherein the look-up key is configured to be presented as a maximum number of beats to the TCAM, wherein N is less than the maximum number of beats, and, for each beat of the N beats, the corresponding beat value identifies which beat of the maximum number of beats to which the corresponding look-up value corresponds.

6. The integrated circuity of claim 5, wherein each entry of the plurality of entries is formed by a maximum number of lines of the TCAM, wherein the corresponding BMV of each line of the plurality of lines identifies which beat of the maximum number of beats to which the corresponding TMV corresponds.

7. The integrated circuit of claim 2, wherein each of the corresponding TMVs include a set of symbols, each indicating one of a logical one, a logical zero, or a don't care and the look-up values of the N input beats include a set of bit values, each indicating a logical one or a logical zero, in which the set of bit values includes half as many bits as a number of symbols in the set of symbols.

8. The integrated circuity of claim 1, wherein the prerequisite determination circuitry for each line is configured to receive an isolated line match indicator which indicates whether a line match occurred with any one of the N beats and prerequisite information from each of N preceding lines, wherein the prerequisite determination circuitry uses the received prerequisite information from the N preceding lines to determine whether the first and second conditions are met.

9. The integrated circuitry of claim 8, wherein the prerequisite determine circuitry for each line does not receive prerequisite information from lines preceding the N preceding lines.

10. The integrated circuitry of claim 1, wherein the TCAM further includes entry match determination circuitry for each line, coupled to receive the corresponding CLM bit and the corresponding extension value of the line, wherein the entry match determination circuitry indicates an entry match when the corresponding CLM bit is asserted and the corresponding extension value of the line indicates it is not extended.

11. The integrated circuitry of claim 1, wherein the look-up key is parsed from a received communication packet.

12. An integrated circuit, comprising:
a ternary content addressable memory (TCAM) having a plurality of lines and a plurality of entries, in which each entry is formed by at least two contiguous lines of the plurality of lines, wherein each line is configured to store a corresponding extension value which indicates whether the line is a last line of an entry of the TCAM or instead extends to a next contiguous line of the entry; and
input compare lanes coupled to receive N beats in a current clock cycle, wherein the N beats correspond to N portions of a look-up key presented for a search operation in the TCAM, N being an integer greater than or equal to two;
wherein the TCAM comprises:
storage circuitry configured to store a corresponding cumulative line match (CLM) bit for each line of the plurality of lines, wherein an asserted CLM bit indicates that an isolated line match for the line to which it corresponds has occurred in a previous clock cycle; and
line circuitry for each line of the plurality of lines configured to, when an isolated line match of a current line of the plurality of lines with any one of the N beats occurs, determining an entry match for a corresponding entry when the corresponding extension value of the current line indicates it is the last line of the corresponding entry and all previous contiguous lines of the corresponding entry have matched in either previous clock cycles as indicated by corresponding CLM bits or in the current clock cycle with any of the N beats.

13. The integrated circuit of claim 12, wherein the line circuitry of each line comprises:
prerequisite determination circuitry configured to receive prerequisite information from line circuitry of a previous line of the plurality of lines, and, in response to the isolated line match of the current line, when the prerequisite information indicates a match prerequisite has been met, indicate that the corresponding CLM bit for the current line is to be asserted in a subsequent clock cycle.

14. The integrated circuit of claim 13, wherein the prerequisite determination circuitry for each line provides prerequisite information to line circuitry of a subsequent line of the plurality of lines based on the prerequisite information received from line circuitry of the previous line, an isolated match indicator of the current line, the corresponding extension value of the current line, and the corresponding CLM bit for the current line.

15. The integrated circuity of claim 13, wherein the prerequisite information is based at least in part on isolated line matches determined in the current clock cycle with any of the N input beats.

16. The integrated circuit of claim 12, wherein each line of the plurality of lines is further configured to store a corresponding ternary match value (TMV) and a corresponding beat match value (BMV), and each beat of the N beats is configured to have a corresponding look-up value and a corresponding beat value.

17. The integrated circuit of claim 16, wherein an isolated line match of the current line occurs when any one of the N beats has a corresponding look-up value and corresponding beat value which matches the corresponding TMV and corresponding BMV of the current line.

18. The integrated circuit of claim 17, wherein each line of the plurality of line further comprises:
BMV comparison circuitry configured to perform up to N comparisons to determine if a match occurs between the corresponding BMV of the current line and the corresponding beat value of any one of the N beats, and
TMV comparison circuitry configured to determine if a match occurs between the corresponding TMV of the current line and the corresponding look-up value of a matching beat from the BMV comparison circuitry whose corresponding beat value matched the corresponding BMV of the current line.

19. The integrated circuit of claim 16, wherein the look-up key is configured to be presented as a maximum number of beats to the TCAM, wherein N is less than the maximum number of beats, and, for each beat of the N beats, the corresponding beat value identifies which beat of the maximum number of beats to which the corresponding look-up value corresponds.

20. The integrated circuity of claim 19, wherein each entry of the plurality of entries is formed by a maximum number of lines of the TCAM, wherein the corresponding BMV of each line of the plurality of lines identifies which beat of the maximum number of beats to which the corresponding TMV corresponds.
